(19) United States
(12) Patent Application Publication
(10) Pub. No.: US 2026/0344045 A1
(43) Pub. Date: Oct. 29, 2026

(54) SEMICONDUCTOR DEVICE AND METHOD OF FORMING THE SAME

(71) Applicant: Vanguard International Semiconductor Corporation, Hsinchu (TW)

(72) Inventor: Tsung-Hsiung LEE, Taoyuan City (TW)

(73) Assignee: Vanguard International Semiconductor Corporation, Hsinchu (TW)

(21) Appl. No.: 19/187,100

(22) Filed: Apr. 23, 2025

(51) Int. Cl. H10D 86/00; H10D 86/01

(52) U.S. Cl. CPC H10D 86/201; H10D 86/01

(57) ABSTRACT

A semiconductor device includes: a semiconductor on insulator (SOI) substrate; and a vertical active element disposed in a first region. The semiconductor on insulator substrate includes: a base plate, and an insulating layer disposed on a frontside of the base plate. The vertical active element includes: a pair of source regions disposed in the semiconductor on insulator substrate; a pair of gate electrodes disposed at opposite sides of the pair of source regions, respectively; and a drain electrode disposed on a backside of the base plate. A portion of the drain electrode is disposed through the base plate and the insulating layer. The semiconductor device further includes: a horizontal active element disposed in a second region; and an isolation structure separating the vertical active element from the horizontal active element.

### BACKGROUND

### TECHNICAL FIELD

The present disclosure relates to a semiconductor device and method of forming the same, and in particular, it relates to a design that integrates a vertical active element with a horizontal active element.

### DESCRIPTION OF THE RELATED ART

The semiconductor integrated circuit (IC) industry has experienced rapid growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, such scaling down has also been accompanied by increased complexity in design and manufacturing of devices incorporating these integrated circuits. As the minimum feature dimensions are continuously reduced, the manufacturing process has become more difficult to implement. Therefore, the formation of a reliable semiconductor device with a smaller feature size is very challenging.

### SUMMARY

An embodiment of the present disclosure provides a semiconductor device includes: a semiconductor on insulator (SOI) substrate; and a vertical active element disposed in a first region. The semiconductor on insulator substrate includes: a base plate, and an insulating layer disposed on a frontside of the base plate. The vertical active element includes: a pair of source regions disposed in the semiconductor on insulator substrate; a pair of gate electrodes disposed at opposite sides of the pair of source regions, respectively; and a drain electrode disposed on a backside of the base plate. A portion of the drain electrode is disposed through the base plate and the insulating layer. The semiconductor device further includes: a horizontal active element disposed in a second region; and an isolation structure separating the vertical active element from the horizontal active element.

Another embodiment of the present disclosure provides a method of forming a semiconductor device includes: providing a semiconductor on insulator substrate; and forming a vertical active element in a first region. Providing the semiconductor on insulator substrate includes: providing a base plate; and forming an insulating layer on a frontside of the base plate. Forming the vertical active element includes: forming a pair of source regions in the semiconductor on insulator substrate; forming a pair of gate electrodes at opposite sides of the pair of source regions, respectively; and depositing a drain electrode on a backside of the base plate. The method further includes: etching the semiconductor on insulator substrate to form an opening through the base plate and the insulating layer from the backside of the base plate, wherein a portion of the drain electrode extends into the opening; forming a horizontal active element in a second region; and forming an isolation structure separating the vertical active element from the horizontal active element.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIGS. 1-9 illustrate cross-sectional views of intermediate stages of a semiconductor device, according to some embodiments of the present disclosure.

FIGS. 10-13 illustrate cross-sectional views of intermediate stages of a semiconductor device, according to other embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity, and does not in itself dictate a relationship between various embodiments and/or configuration discussed.

Furthermore, in some embodiments of the present disclosure, terms that describe a joining or connecting action, such as “connect”, “interconnect”, or the like, unless otherwise defined, may include embodiments in which two features are formed in direct contact, and they may also include embodiments in which additional features may be formed between the two features.

Furthermore, spatially relative terms, such as “beneath,” “below,” “lower,” “on,” “above,” “upper,” and the like, may be used herein for ease of description to describe one element or feature’s relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean ±20% of the stated value, more typically ±10% of the stated value, more typically ±5% of the stated value, more typically ±3% of the stated value, more typically ±2% of the stated value, more typically ±1% of the stated value, and even more typically ±0.5% of the stated value. The stated value of the present disclosure is an approximate value. That is, when there is no specific description of the terms “about,” “approximately” and “substantially”, the stated value includes the meaning of “about,” “approximately” or “substantially”.

Some embodiments of the disclosure are described. Additional operations can be provided before, during, and/or after the stages described in these embodiments. Additional features can be added to the semiconductor device. Some of the features described below can be replaced or eliminated for different embodiments. Although some embodiments are discussed with operations performed in a particular order, these operations may be performed in another logical order.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

In the present technology, a horizontal active element (for example, a lateral-diffused metal-oxide semiconductor (LDMOS) transistor) may typically generate sufficiently high breakdown voltage and sufficiently low on-state resistance by adjusting the doping concentration and structural profile of every semiconductor region of the horizontal active element, in order to further optimize the overall performance. However, in a more complex design of the horizontal active element (for example, an integrated bipolar complementary metal oxide semiconductor – double diffused metal oxide semiconductor (BCD) transistor), it may be difficult to achieve an effective isolation.

In addition, a present vertical active element may include a metal-oxide semiconductor field effect transistor (MOSFET), for example, adopting a split-gate transistor (SGT) to maintain the breakdown voltage and to reduce the on-state resistance. The arrangement of the “split-gate” structure may drive the electric field from the frontside of the base plate toward the drain terminal at the backside of the base plate, thereby increasing the breakdown voltage and decreasing the on-state resistance.

It should be appreciated that the channel of the horizontal active element may be extended in the horizontal direction, while the channel of the vertical active element may be extended in the vertical direction. Therefore, if the horizontal active element and the vertical active element are to be disposed onto the same wafer, the present technology may need to form the horizontal active element and the vertical active element in different manufacturing processes. Furthermore, since it is already difficult to achieve the effective isolation in the horizontal active element, the isolation may be even more challenging when the horizontal active element and the vertical active element are integrated. The inventor has discovered that a semiconductor on insulator (SOI) substrate may be combined with a deep trench isolation (DTI) structure to achieve the complete isolation. Moreover, in response to the implementation of the semiconductor on insulator substrate, the backside process (including grinding, etching, depositing, or the like) may be implemented to design the drain electrode formed on the backside of the base plate of the semiconductor on insulator substrate to be extended through the base plate and the insulating layer, in order to constitute an innovative drain terminal.

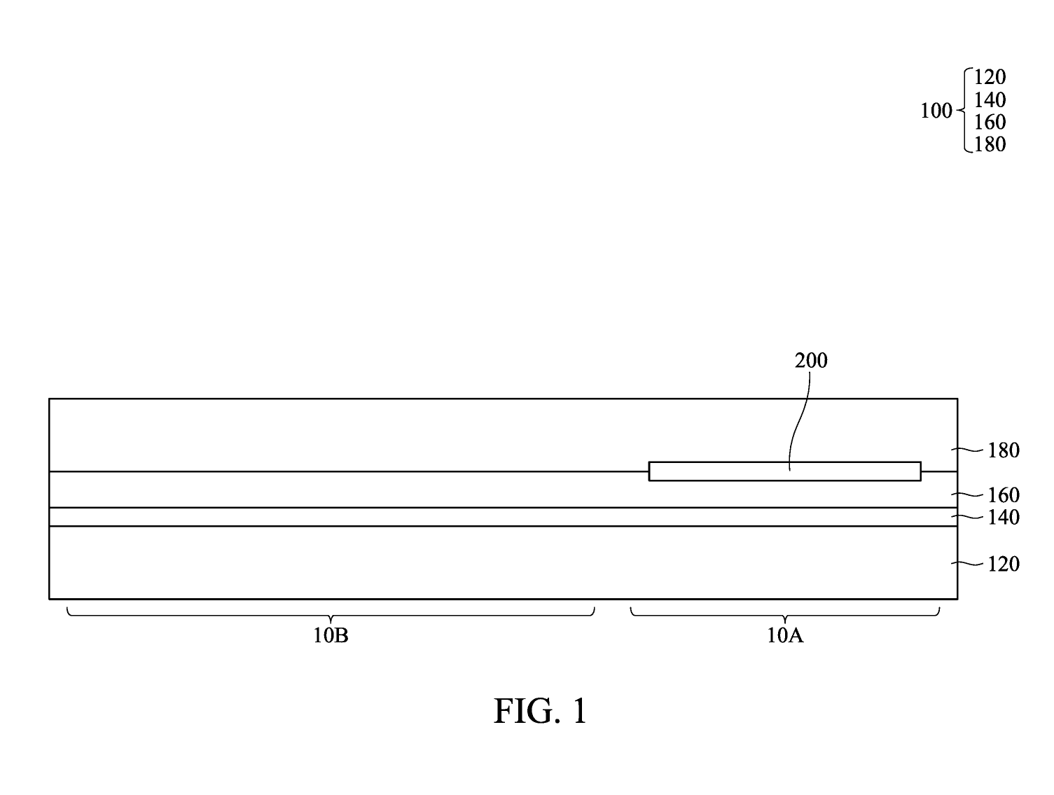

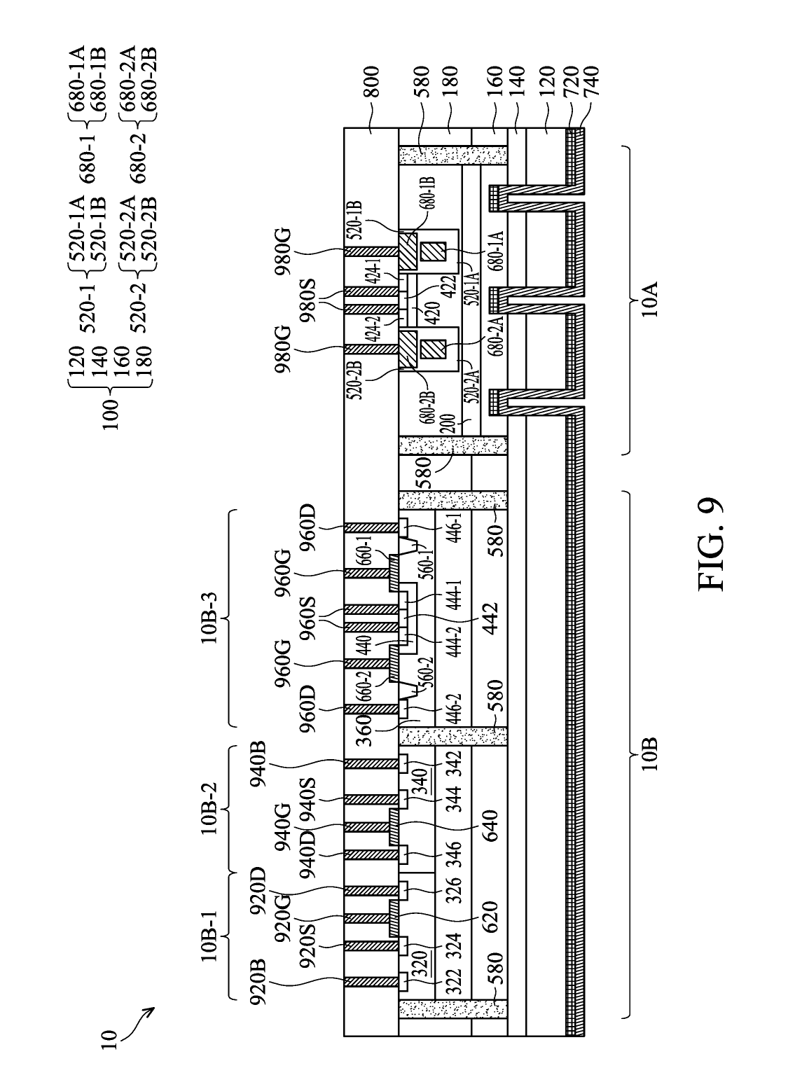

FIGS. 1-9 illustrate cross-sectional views of intermediate stages of a semiconductor device 10, according to some embodiments of the present disclosure. In the present embodiment, the semiconductor device 10 only illustrates a portion of the horizontal active element and a portion of the vertical active element. In some embodiments, a semiconductor device may typically include any quantity of active components or passive components. The active components include metal-oxide semiconductor (MOS) transistors, complementary metal-oxide semiconductor (CMOS) transistors, lateral-diffused metal-oxide semiconductor transistors, bipolar complementary metal oxide semiconductor – double diffused metal oxide semiconductor transistors, planar transistors, fin field-effect transistors (finFET), gate-all-around field-effect transistors (GAA FET), split-gate transistor, the like, or a combination thereof. The passive components include metal lines, capacitors, inductors, resistors, diodes, bonding pads, or the like. For simplicity, FIG. 9 only shows illustrative bipolar complementary metal oxide semiconductor – double diffused metal oxide semiconductor transistor and split-gate transistor.

Referring to FIG. 1, the semiconductor device 10 may be compartmentalized into a first region 10A and a second region 10B. The initial structure of the semiconductor device 10 may include a semiconductor on insulator substrate 100 and a buried layer 200. In some embodiments, the semiconductor on insulator substrate 100 may include a base plate 120, an insulating layer 140, an epitaxial layer 160, and an epitaxial layer 180. In other embodiments, the semiconductor on insulator substrate 100 may only include the base plate 120, the insulating layer 140, and the epitaxial layer 160, while the epitaxial layer 180 may be an additional semiconductor layer.

In some embodiments, the base plate 120 of the semiconductor on insulator substrate 100 may be, for example, a wafer or a chip, but the present disclosure is not limited thereto. In some embodiment, the base plate 120 may be a semiconductor substrate, for example, silicon (Si) substrate. Furthermore, in some embodiments, the semiconductor substrate may also be an elemental semiconductor including germanium (Ge), a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb), an alloy semiconductor including silicon germanium (SiGe) alloy, gallium arsenic phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenic phosphide (GaInAsP) alloy, or a combination thereof.

Furthermore, the base plate 120 may be a first conductive type or a second conductive type that is different from the first conductive type. In the following embodiments, the first conductive type and the second conductive type may represent p-type and n-type, respectively. The first conductive type (p-type) and the second conductive type (n-type) may be respectively doped with suitable dopants (or impurities). P-type dopants may include boron (B), indium (In), aluminum (Al), or gallium (Ga), while n-type dopants may include phosphorus (P) or arsenic (As). In a specific embodiment of the present disclosure, the base plate 120 may be the second conductive type (n-type), with a doping concentration between 3×10¹⁹ cm⁻³ and 8×10¹⁹ cm⁻³.

Still referring to FIG. 1, the insulating layer 140 may be disposed on the base plate 120. In some embodiments, the insulating layer 140 may encapsulate the base plate 120, and may be continuously extended across the first region 10A and the second region 10B. According to some embodiments of the present disclosure, the insulating layer 140 may provide insulation for the overlying structures from the underlying base plate 120. The insulating layer 140 may be a buried oxide (BOX). The thickness of the insulating layer 140 may be between 0.5μm and 5μm.

Referring to FIG. 1, the epitaxial layer 160 may be disposed on the insulating layer 140. In some embodiments, the epitaxial layer 160 may have the second conductive type (n-type), with a doping concentration between 6×10¹ ⁵ cm⁻³ and 2×10¹ ⁷ cm⁻³. In a specific embodiment of the present disclosure, the base plate 120 and the epitaxial layer 160 may have the same conductive type, and the doping concentration of the base plate 120 is larger than the doping concentration of the epitaxial layer 160. The materials of the epitaxial layer 160 may include silicon, silicon germanium, silicon carbide, the like, or a combination thereof.The thickness of the epitaxial layer 160 may be between 1μm and 7μm. The epitaxial layer 160 may be formed by epitaxial process, which may include metal organic chemical vapor deposition (MOCVD), liquid phase epitaxy (LPE), vapor phase epitaxy (VPE), hydride vapor phase epitaxy (HVPE), selective epitaxial growth (SEG), molecular beam epitaxy (MBE), the like, or a combination thereof.

Still referring to FIG. 1, the epitaxial layer 180 may be disposed on the epitaxial layer 160. In some embodiments, the epitaxial layer 180 may have the second conductive type (n-type), with a doping concentration between 6×10¹ ⁵ cm⁻³ and 2×10¹ ⁷ cm⁻³. In a specific embodiment of the present disclosure, the base plate 120, the epitaxial layer 160, and the epitaxial layer 180 may all have the same conductive type, and the doping concentration of the epitaxial layer 160 is larger than the doping concentration of the epitaxial layer 180. The epitaxial layer 160 may be disposed between the insulating layer 140 and the epitaxial layer 180.The thickness of the epitaxial layer 180 may be between 1μm and 7μm. The materials and the formation of the epitaxial layer 180 may be similar to those of the epitaxial layer 160, and the details are not described again herein to avoid repetition.

It should be appreciated that since the subsequently formed discrete device is the second conductive type (n-type), the base plate 120, the epitaxial layer 160, and the epitaxial layer 180 all need to be the second conductive type (n-type), in order to facilitate the current conduction in the vertical channel. If the epitaxial layer 160 and the epitaxial layer 180 are both configured to be the first conductive type (p-type), an additional well region of the second conductive type (n-type) may be formed surrounding the discrete device (for example, the split-gate transistor), so the discrete device may continue to operate normally. Furthermore, the epitaxial layer 160 may be configured to have a relatively higher doping concentration to reduce the overall on-state resistance of the discrete device, while the epitaxial layer 180 may be configured to have a relatively lower doping concentration to maintain the overall breakdown voltage of the discrete device.

Referring to FIG. 1, the semiconductor device 10 may include the buried layer 200 in the first region 10A and disposed within the epitaxial layer 160 and within the epitaxial layer 180. In some embodiments, the buried layer 200 may have the second conductive type (n-type). According to some embodiments of the present disclosure, the buried layer 200 may reduce the overall on-state resistance of the discrete device. The configuration of the buried layer 200 may be optional. In other words, when the semiconductor on insulator 100 is applied, the buried layer 200 may be omitted. Alternatively, if the breakdown voltage of the horizontal active element of the second region 10B is significantly affected by the backside bias, the buried layer 200 may be disposed in the second region 10B to reduce the backside effect. The vertical dimension of the buried layer 200 may be between 0.5μm and 2μm. The lateral dimension of the buried layer 200 may span across the first region 10A. The formation of the buried layer 200 may include ion implanting the n-type dopants (for example phosphorus or arsenic) in the epitaxial layer 160 and performing thermal treatment to drive in the implanted ions into the epitaxial layer 160 before forming the epitaxial layer 180. After that, the epitaxial layer 180 may then be formed on the epitaxial layer 160. In some embodiments, since the epitaxial layer 180 is formed under the high temperature condition, thus the implanted ions may be diffused into the epitaxial layer 180. As shown in FIG. 1, the buried layer 200 is located near the interface between the epitaxial layer 160 and the epitaxial layer 180, with a portion in the epitaxial layer 160, and another portion in the epitaxial layer 180. In other words, the buried layer 200 may be extended upward and downward from the interface between the epitaxial layer 160 and the epitaxial layer 180.

In some embodiments, the doping concentration of the buried layer 200 may be between 5×10¹ ⁷ cm⁻³ and 1×10²⁰ cm⁻³. According to some embodiments of the present disclosure, the doping concentration of the base plate 120 may be larger than the doping concentration of the buried layer 200, the doping concentration of the buried layer 200 may be larger than the doping concentration of the epitaxial layer 160, and the doping concentration of the epitaxial layer 160 may be larger than the doping concentration of the epitaxial layer 180. The configuration of the epitaxial layer 160 with the relatively higher doping concentration below the buried layer 200, and the configuration of the epitaxial layer 180 with the relatively lower doping concentration above the buried layer 200 may be an ideal design to further reduce the on-state resistance.

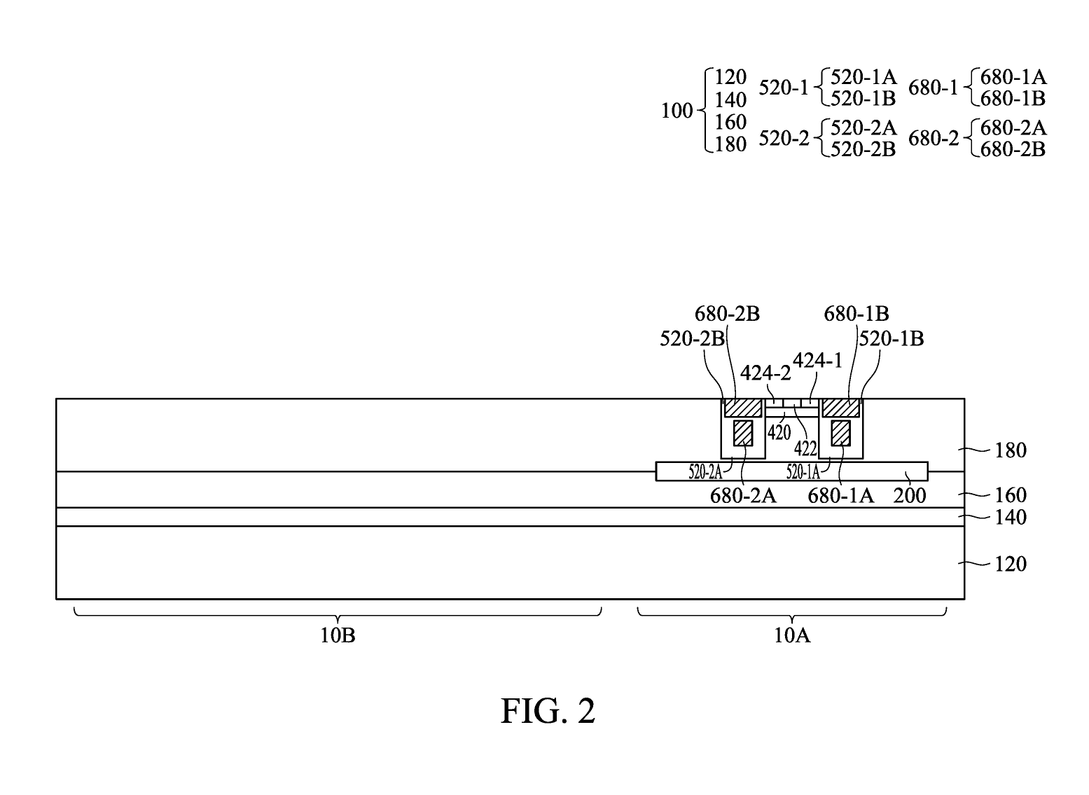

Referring to FIG. 2, the vertical active element may be disposed in the first region 10A of the semiconductor on insulator substrate 100, in which the vertical active element may be the discrete device. Although the semiconductor device 10 illustrates the split-gate transistor as the example of the discrete device, but the present disclosure is not limited thereto. For example, the discrete device may include switch trench metal-oxide semiconductor transistor or vertical-diffused metal-oxide semiconductor transistor. In a conventional split-gate transistor, the source terminal and the gate terminal may be configured at the frontside of the base plate, while the drain terminal may be configured at the backside of the base plate. Therefore, the channel may be formed extending from the frontside surface of the base plate toward the backside of the base plate in the vertical direction.

It is worth noted that the semiconductor on insulator substrate 100 is implemented in order to integrate the horizontal active element and the vertical active element, and to achieve the complete isolation. If the drain terminal of the split-gate transistor is still disposed on the backside of the base plate 120 of the semiconductor on insulator substrate 100, then the insulating layer 140 would sever the original channel path, so the drain terminal is unable to conduct. According to some embodiments of the present disclosure, the drain terminal of the split-gate transistor may be disposed through the base plate 120 and the insulating layer 140, in order to prevent the insulating layer 140 from affecting the operation of the split-gate transistor. The split-gate transistor in the first region 10A may still have the channel in the vertical direction. However, the current in the channel will conduct at the portion of the drain terminal disposed through the base plate 120 and the insulating layer 140, which in turn achieves the effective operation of the split-gate transistor.

Initially, the well region 420 may be disposed within the epitaxial layer 180. The well region 420 may be extended vertically from the upper surface of the epitaxial layer 180 into the epitaxial layer 180. In some embodiments, the well region 420 may include the subsequently formed heavily doped region 422, source region 424-1, and source region 424-2. According to some embodiments of the present disclosure, the well region 420 may be the first conductive type (p-type), with a doping concentration between 1×10¹ ⁵ cm⁻³ and 2×10¹ ⁷ cm⁻³. The thickness of the well region 420 may be between 0.3μm and 1.5μm. The well region 420 may be formed by, for example, the ion implantation and/or the diffusion process.

Still referring to FIG. 2, the heavily doped region 422, the source region 424-1, and the source region 424-2 may be disposed within the well region 420, and may be extended downward from the upper surface of the well region 420. According to some embodiments of the present disclosure, the heavily doped region 422 may be the first conductive type (p-type), while the source region 424-1 and the source region 424-2 may be the second conductive type (n-type). The heavily doped region 422, the source region 424-1, and the source region 424-2 may be laterally adjoined with each other, and the heavily doped region 422 may be laterally sandwiched between the source region 424-1 and the source region 424-2. The formation of the heavily doped region 422, the source region 424-1, and the source region 424-2 may be similar to that of the well region 420, and the details are not described again herein to avoid repetition.

In some embodiments, the doping concentration of the heavily doped region 422 may be between 1×10¹ ⁸ cm⁻³ and 1×10²² cm⁻³. The heavily doped region 422 may be coupled to the subsequently formed source contacts 980S simultaneously with the source region 424-1 and the source region 424-2. The thickness of the heavily doped region 422 may be between 0.1μm and 0.5μm. According to some embodiments of the present disclosure, since the well region 420 and the heavily doped region 422 have the same conductive type, the heavily doped region 422 may serve as the source terminal main body that connects the source region 424-1 and the source region 424-2, and may play a critical role for the source terminal to be electrically ground.

In some embodiments, the doping concentration of the source region 424-1 and the source region 424-2 may be between 1×10¹ ⁸ cm⁻³ and 1×10²² cm⁻³. The thickness of the source region 424-1 and the source region 424-2 may be between 0.1μm and 0.5μm. According to some embodiments of the present disclosure, the source region 424-1 and the source region 424-2 may function as the source terminal for the split-gate transistor.

Referring to FIG. 2, a dielectric layer 520-1, a dielectric layer 520-2, an electrode 680-1, and an electrode 680-2 may be disposed in the epitaxial layer 180. The dielectric layer 520-1 may include a first portion 520-1A and a second portion 520-1B. The dielectric layer 520-2 may include a first portion 520-2A and a second portion 520-2B. The electrode 680-1 may include a first structure 680-1A and a second structure 680-1B. The electrode 680-2 may include a first structure 680-2A and a second structure 680-2B. In some embodiments, the second portion 520-1B and the second structure 680-1B may constitute a gate structure laterally located on one side of the well region 420 close to the source region 424-1, while the second portion 520-2B and the second structure 680-2B may constitute another gate structure laterally located on another side of the well region 420 close to the source region 424-2. Moreover, the first portion 520-1A and the first structure 680-1A may constitute a split-gate structure below the gate structure (including the second portion 520-1B and the second structure 680-1B), while the first portion 520-2A and the first structure 680-2A may constitute another split-gate structure below the gate structure (including the second portion 520-2B and the second structure 680-2B).

In some embodiments, the gate structure (including the second portion 520-1B and the second structure 680-1B) and the gate structure (including the second portion 520-2B and the second structure 680-2B) may be coupled to the subsequently formed gate contacts 980G, respectively. The first structure 680-1A and the second structure 680-1B of the electrode 680-1 may be insulated from each other, and the first structure 680-2A and the second structure 680-2B of the electrode 680-2 may be insulated from each other. According to some embodiments of the present disclosure, the gate structure (including the second portion 520-1B and the second structure 680-1B), the gate structure (including the second portion 520-2B and the second structure 680-2B), the split-gate structure (including the first portion 520-1A and the first structure 680-1A), and the split-gate structure (including the first portion 520-2A and the first structure 680-2A) may be connected to the same electric potential (not shown) as the source terminal of the split-gate transistor.

The materials of the dielectric layer 520-1 and the dielectric layer 520-2 may include silicon oxide (SiO), silicon nitride (SiN), silicon oxynitride (SiON), or a multiple layer thereof. In other embodiments, the dielectric layer 520-1 and the dielectric layer 520-2 may include high-k materials, which have the dielectric constant approximately larger than 7.0. High-k materials may include metal oxides, or silicates of hafnium (Hf), aluminum, zirconium (Zr), lanthanum (La), magnesium (Mg), barium (Ba), titanium (Ti), lead (Pb), the like, or a combination thereof. Metal oxides may include hafnium oxide (HfO₂), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (La₂O₃), aluminum oxide (Al₂O₃), aluminum silicon oxide (AlSiO), zirconium oxide (ZrO₂), titanium oxide (TiO), tantalum oxide (Ta₂O₅), yttrium oxide (Y₂O₃), or the like.

The thickness of the second portion 520-1B of the dielectric layer 520-1 and the second portion 520-2B of the dielectric layer 520-2 may be between 250Å and 1500Å. The thickness of the first portion 520-1A of the dielectric layer 520-1 and the first portion 520-2A of the dielectric layer 520-2 may be between 1000Å and 6000Å. According to some embodiments of the present disclosure, the thickness of the first portion 520-1A and the first portion 520-2A may be larger than the thickness of the second portion 520-1B and the second portion 520-2B. It should be appreciated that if the thickness of the second portion 520-1B and the second portion 520-2B is too large, then the threshold voltage generated may be too high. If the thickness of the first portion 520-1A and the first portion 520-2A is too small, then the insulating function may be compromised. The dielectric layer 520-1 and the dielectric layer 520-2 may be formed by chemical vapor deposition (CVD), molecular beam deposition (MBD), atomic layer deposition (ALD), plasma-enhanced chemical vapor deposition (PECVD), the like, or a combination thereof.

The materials of the electrode 680-1 and the electrode 680-2 may include amorphous silicon, polysilicon, poly-SiGe, metal nitride (such as titanium nitride (TiN), tantalum nitride (TaN), tungsten nitride (WN), titanium aluminum nitride (TiAlN), or the like), metal silicide (such as nickel silicide (NiSi), cobalt silicide (CoSi), tantalum silicon nitride (TaSiN), or the like), metal carbide (such as tantalum carbide (TaC), tantalum carbonitride (TaCN), or the like), metal oxide, or metals. Metals may include cobalt (Co), ruthenium (Ru), aluminum, palladium (Pd), platinum (Pt), tungsten (W), copper (Cu), titanium, tantalum (Ta), silver (Ag), gold (Au), nickel (Ni), manganese (Mn), zirconium, the like, a combination thereof, or a multiple layer thereof.

In some embodiments, the first portion 520-1A and the first portion 520-2A may be disposed on the opposite sides and the bottom portion of the first structure 680-1A and the first structure 680-2, respectively. The second portion 520-1B and the second portion 520-2B may be disposed on the opposite sides and the bottom portion of the second structure 680-1B and the second structure 680-2B, respectively. Furthermore, the portion of the second portion 520-1B that is on the bottom portion of the second structure 680-1B may be between the first structure 680-1A and the second structure 680-1B, while the portion of the second portion 520-2B that is on the bottom portion of the second structure 680-2B may be between the first structure 680-2A and the second structure 680-2B. In other words, the first structure 680-1A and the second structure 680-1B of the electrode 680-1 may be “split” by a portion of the dielectric layer 520-1, while the first structure 680-2A and the second structure 680-2B of the electrode 680-2 may be “split” by a portion of the dielectric layer 520-2. This demonstrates the “split-gate” feature of the present disclosure.

The first structure 680-1A and the first structure 680-2A may have the lateral dimension between 0.18μm and 2μm, and the vertical dimension between 0.8μm and 10μm. The second structure 680-1B and the second structure 680-2B may have the lateral dimension between 0.18μm and 2μm, and the vertical dimension between 0.3μm and 2μm. According to some embodiments of the present disclosure, the lateral dimension of the second structure 680-1B and the second structure 680-2B may be larger than the lateral dimension of the first structure 680-1A and the first structure 680-2A. The vertical dimension of the first structure 680-1A and the first structure 680-2A may be larger than the vertical dimension of the second structure 680-1B and the second structure 680-2B. The electrode 680-1 and the electrode 680-2 may be formed by physical vapor deposition (PVD), atomic layer deposition, plating, sputtering, evaporating, the like, or a combination thereof.

In some embodiments, first openings (not shown) may first be formed extending into the epitaxial layer 180 at opposite sides of the well region 420. After the formation of the first openings, second openings may be formed from the bottom surface of the first openings. The second openings may still be extended in the epitaxial layer 180, and may be vertically spaced apart from the underlying buried layer 200. The lateral dimension of the first openings may be substantially equal to the lateral dimension of the second openings, while the vertical dimension of the second openings may be larger than the vertical dimension of the first openings. The subsequently formed dielectric layer 520-1, dielectric layer 520-2, electrode 680-1, and electrode 680-2 may adopt the profile of the first openings and the second openings. The first openings and the second openings may be patterned by the lithography process, followed by the etching process. The lithography process may include photoresist coating, soft baking, exposure, post-exposure baking, development, the like, or a combination thereof. The etching process may include dry etch process, wet etch process, the like, or a combination thereof.

The wet etch process may be isotropic, and may be performed in wet etchants. In some embodiments, suitable etchants for the wet etch process may include sulfuric acid (H₂SO₄), hydrochloric acid (HCl), hydrogen bromide (HBr), ammonia (NH₃), diluted hydrofluoric acid (dHF), hydrofluoric acid (HF), potassium hydroxide (KOH), nitric acid (HNO₃), acetic acid (CH₃COOH), succinic acid (C₄H₆O₄), citric acid (C₆H₈O₇), the like, or a combination thereof, but the present disclosure is not limited thereto.

The dry etch process may include anisotropic plasma etching, such as reactive ion etching (RIE), inductively coupled plasma (ICP), capacitively coupled plasma (CCP), the like, or a combination thereof, but the present disclosure is not limited thereto. The dry etch process may be performed in the environment of the selected process gas. The illustrative process gas may include nitrogen (N₂), ammonia, oxygen (O₂), dinitrogen monoxide (N₂O), argon (Ar), helium (He), hydrogen (H₂), tetrafluoromethane (CF₄), sulfur hexafluoride (SF₆), difluoromethane (CH₂F₂), trifluoromethane (CHF₃), hexafluoroethane (C₂F₆), chlorine (Cl₂), trichloromethane (CHCl₃), carbon tetrachloride (CCl₄), boron trichloride (BCl₃), hydrogen bromide, bromoform (CHBr₃), or the like, but the present disclosure is not limited thereto.

In some embodiments, the first portion 520-1A of the dielectric layer 520-1 and the first portion 520-2A of the dielectric layer 520-2 may be respectively formed in the second openings using any suitable deposition process mentioned above, followed by forming the first structure 680-1A of the electrode 680-1 and the first structure 680-2A of the electrode 680-2 respectively in the remainder of the second openings using any suitable deposition process mentioned above. More specifically, the dielectric material and the electrode material may be sequentially filled into the second openings after performing the etching process to form the second openings, and before removing the lithography pattern. After the second openings are filled, the planarization process (such as chemical mechanical polish (CMP) or etch back) may be performed to remove the lithography pattern, along with the excessive dielectric material and electrode material. The remainder of the dielectric material and the electrode material then becomes the first portion 520-1A of the dielectric layer 520-1 and the first portion 520-2A of the dielectric layer 520-2, and the first structure 680-1A of the electrode 680-1 and the first structure 680-2A of the electrode 680-2, respectively.

In some embodiments, the second portion 520-1B of the dielectric layer 520-1 and the second portion 520-2B of the dielectric layer 520-2 may be respectively formed in the first openings using any suitable deposition process mentioned above, followed by forming the second structure 680-1B of the electrode 680-1 and the second structure 680-2B of the electrode 680-2 respectively in the remainder of the first openings using any suitable deposition process mentioned above. More specifically, the same dielectric material may be conformally formed on the sidewalls of the first openings, the top surfaces of the first portion 520-1A and the first structure 680-1A, and the top surfaces of the first portion 520-2A and the first structure 680-2A. After that, the first openings may be completely filled with the same electrode material. The same planarization process may be performed to remove the excessive dielectric material and electrode material outside the first openings. After the planarization process, the top surfaces of the epitaxial layer 180, the dielectric material, and the electrode material may be level with each other. The remainder of the dielectric material and the electrode material then becomes the second portion 520-1B of the dielectric layer 520-1 and the second portion 520-2B of the dielectric layer 520-2, and the second structure 680-1B of the electrode 680-1 and the second structure 680-2B of the electrode 680-2, respectively.

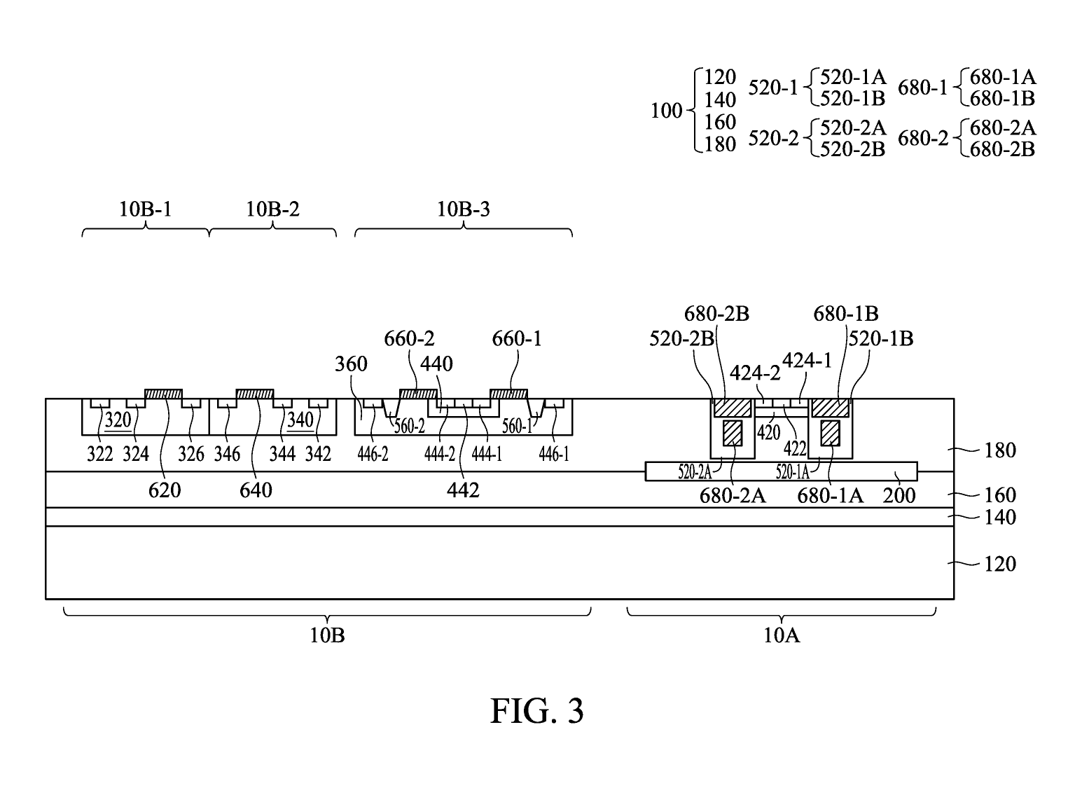

Referring to FIG. 3, the horizontal active element may be disposed in the second region 10B of the semiconductor on insulator substrate 100, and may include a first transistor 10B-1, a second transistor 10B-2, and a third transistor 10B-3. The first transistor 10B-1 may be a metal-oxide semiconductor transistor having the second conductive type (n-type). The second transistor 10B-2 may be a metal-oxide semiconductor transistor having the first conductive type (p-type). The third transistor 10B-3 may be a lateral-diffused metal-oxide semiconductor transistor having the second conductive type (n-type). In some embodiments, the first transistor 10B-1 may be adjoined with the second transistor 10B-2, while the second transistor 10B-2 may be spaced apart from the third transistor 10B-3. Different from the vertical active element in the first region 10A, the first transistor 10B-1, the second transistor 10B-2, and the third transistor 10B-3 may have the channels in the horizontal direction. According to a specific embodiment of the present disclosure, the first transistor 10B-1, the second transistor 10B-2, and the third transistor 10B-3 may constitute the horizontal active element (for example, the bipolar complementary metal oxide semiconductor – double diffused metal oxide semiconductor transistor).

Initially, a well region 320 of the first transistor 10B-1, a well region 340 of the second transistor 10B-2, and a high-voltage well region 360 of the third transistor 10B-3 may be disposed within the epitaxial layer 180. The well region 320, the well region 340, and the high-voltage well region 360 may be extended vertically from the upper surface of the epitaxial layer 180 into the epitaxial layer 180. According to some embodiments of the present disclosure, the well region 320 may be the first conductive type (p-type), while the well region 340 and the high-voltage well region 360 may be the second conductive type (n-type). The well region 320 and the well region 340 may be laterally adjoined with each other, while the well region 340 and the high-voltage well region 360 may be laterally spaced apart from each other. The formation of the well region 320, the well region 340, and the high-voltage well region 360 may be similar to that of the well region 420, and the details are not described again herein to avoid repetition.

In some embodiments, the doping concentration of the well region 320 may be between 1×10¹ ⁵ cm⁻³ and 2×10¹⁷ cm⁻³. The thickness of the well region 320 may be between 0.3μm and 1.5μm. The well region 320 may include the subsequently formed main body region 322, source region 324, and drain region 326. Moreover, a gate structure 620 may be subsequently formed on the surface of the well region 320 in the epitaxial layer 180. The gate structure 620 may be laterally located between the source region 324 and the drain region 326.

In some embodiments, the doping concentration of the well region 340 may be between 1×10¹ ⁵ cm⁻³ and 2×10¹⁷ cm⁻³. The thickness of the well region 340 may be between 0.3μm and 1.5μm. The well region 340 may include the subsequently formed main body region 342, source region 344, and drain region 346. Moreover, a gate structure 640 may be subsequently formed on the surface of the well region 340 in the epitaxial layer 180. The gate structure 640 may be laterally located between the source region 344 and the drain region 346.

In some embodiments, the doping concentration of the high-voltage well region 360 may be between 1×101 5 cm-3 and 2×1017 cm-3. The thickness of the high-voltage well region 360 may be between 0.3μm and 1.5μm. The high-voltage well region 360 may include the subsequently formed well region 440, drain region 446-1, drain region 446-2, isolation structure 560-1, and isolation structure 560-2. The well region 440 may further include a heavily doped region 442, a source region 444-1, and a source region 444-2. Moreover, a gate structure 660-1 and a gate structure 660-2 may be subsequently formed on the surface of the high-voltage well region 360 in the epitaxial layer 180. The gate structure 660-1 may be laterally located between the source region 444-1 and the drain region 446-1, while the gate structure 660-2 may be laterally located between the source region 444-2 and the drain region 446-2. The isolation structure 560-1 may laterally separate the drain region 446-1 from the gate structure 660-1, while the isolation structure 560-2 may laterally separate the drain region 446-2 from thegate structure 660

Still referring to FIG. 3, the main body region 322, the source region 324, and the drain region 326 may be disposed within the well region 320, which may be extended downward from the upper surface of the well region 320. According to some embodiments of the present disclosure, the main body region 322 may be the first conductive type (p-type), while the source region 324 and the drain region 326 may be the second conductive type (n-type). The main body region 322, the source region 324, and the drain region 326 may be laterally spaced apart. The formation of the main body region 322, the source region 324, and the drain region 326 may be similar to that of the well region 420, and the details are not described again herein to avoid repetition.

In some embodiments, the doping concentration of the main body region 322 may be between 1×10¹ ⁸ cm⁻³ and 1×10²² cm⁻³. The main body region 322 may be coupled to the subsequently formed main body contact 920B. The thickness of the main body region 322 may be between 0.1μm and 0.5μm. According to some embodiments of the present disclosure, since the well region 320 and the main body region 322 have the same conductive type, the main body region 322 may serve as the main body terminal for the first transistor 10B-1.

In some embodiments, the doping concentration of the source region 324 may be between 1×10¹ ⁸ cm⁻³ and 1×10²² cm⁻³. The source region 324 may be coupled to the subsequently formed source contact 920S. The thickness of the source region 324 may be between 0.1μm and 0.5μm. According to some embodiments of the present disclosure, the source region 324 may serve as the source terminal for the first transistor 10B-1.

In some embodiments, the doping concentration of the drain region 326 may be between 1×10¹ ⁸ cm⁻³ and 1×10²² cm⁻³. The drain region 326 may be coupled to the subsequently formed drain contact 920D. The thickness of the drain region 326 may be between 0.1μm and 0.5μm. According to some embodiments of the present disclosure, the drain region 326 may serve as the drain terminal for the first transistor 10B-1.

Referring to FIG. 3, the main body region 342, the source region 344, and the drain region 346 may be disposed within the well region 340, which may be extended downward from the upper surface of the well region 340. According to some embodiments of the present disclosure, the main body region 342 may be the second conductive type (n-type), while the source region 344 and the drain region 346 may be the first conductive type (p-type). The main body region 342, the source region 344, and the drain region 346 may be laterally spaced apart. The formation of the main body region 342, the source region 344, and the drain region 346 may be similar to that of the well region 420, and the details are not described again herein to avoid repetition.

In some embodiments, the doping concentration of the main body region 342 may be between 1×10¹ ⁸ cm⁻³ and 1×10²² cm⁻³. The main body region 342 may be coupled to the subsequently formed main body contact 940B. The thickness of the main body region 342 may be between 0.1μm and 0.5μm. According to some embodiments of the present disclosure, since the well region 340 and the main body region 342 have the same conductive type, the main body region 342 may serve as the main body terminal for the second transistor 10B-2.

In some embodiments, the doping concentration of the source region 344 may be between 1×10¹ ⁸ cm⁻³ and 1×10²² cm⁻³. The source region 344 may be coupled to the subsequently formed source contact 940S. The thickness of the source region 344 may be between 0.1μm and 0.5μm. According to some embodiments of the present disclosure, the source region 344 may serve as the source terminal for the second transistor 10B-2.

In some embodiments, the doping concentration of the drain region 346 may be between 1×10¹ ⁸ cm⁻³ and 1×10²² cm⁻³. The drain region 346 may be coupled to the subsequently formed drain contact 940D. The thickness of the drain region 346 may be between 0.1μm and 0.5μm. According to some embodiments of the present disclosure, the drain region 346 may serve as the drain terminal for the second transistor 10B-2.

Still referring to FIG. 3, the well region 440, the drain region 446-1, the drain region 446-2, the isolation structure 560-1, and the isolation structure 560-2 may be disposed within the high-voltage well region 360, which may be extended downward from the upper surface of the high-voltage well region 360. According to some embodiments of the present disclosure, the well region 440 may be the first conductive type (p-type), while the drain region 446-1 and the drain region 446-2 may be the second conductive type (n-type). The well region 440, the drain region 446-1, and the drain region 446-2 may be laterally spaced apart. The isolation structure 560-1 and the isolation structure 560-2 may be adjoined with the drain region 446-1 and the drain region 446-2, respectively. The formation of the well region 440, the drain region 446-1, and the drain region 446-2 may be similar to that of the well region 420, and the details are not described again herein to avoid repetition.

In some embodiments, the doping concentration of the well region 440 may be between 1×10¹ ⁵ cm⁻³ and 2×10¹⁸ cm⁻³. The thickness of the well region 440 may be between 0.3μm and 1.5μm. The well region 440 may include the subsequently formed heavily doped region 442, source region 444-1, and source region 444-2. Moreover, the gate structure 660-1 and the gate structure 660-2 may be partially in contact with the well region 440.

In some embodiments, the doping concentration of the drain region 446-1 and the drain region 446-2 may be between 1×10¹ ⁸ cm⁻³ and 1×10²² cm⁻³. The drain region 446-1 and the drain region 446-2 may be coupled to the subsequently formed drain contacts 960D, respectively. The thickness of the drain region 446-1 and the drain region 446-2 may be between 0.1μm and 0.5μm. According to some embodiments of the present disclosure, the drain region 446-1 and the drain region 446-2 may serve as the drain terminal for the third transistor 10B-3.

In some embodiments, the isolation structure 560-1 and the isolation structure 560-2 may be shallow trench isolation (STI) structures or local oxidation of silicon (LOCOS) structures. As mentioned previously, the isolation structure 560-1 may laterally separate the drain region 446-1 from the gate structure 660-1, while the isolation structure 560-2 may laterally separate the drain region 446-2 from the gate structure 660-2. According to some embodiments of the present disclosure, the isolation structure 560-1 and the isolation structure 560-2 may prevent the generation of high electric field due to the junction breakdown. The depth of the isolation structure 560-1 and the isolation structure 560-2 may be between 0.2μm and 0.6μm. It is worth noted that the depth of the isolation structure 560-1 and the isolation structure 560-2 should be larger than the thickness of the drain region 446-1 and the drain region 446-2, in order to effectively block the high electric field from the drain region 446-1 and the drain region 446-2.

In some embodiments, the formation of the isolation structure 560-1 and the isolation structure 560-2 may include, for example, forming an insulating layer on the semiconductor on insulator substrate 100, selectively etching the insulating layer and the semiconductor on insulator substrate 100 to form trenches that extend from the top surface of the semiconductor on insulator substrate 100 to a position within the semiconductor on insulator substrate 100, in which the trenches are located between adjacent active regions. Next, the rich nitrogen-containing (such as silicon oxynitride or the like) liners may be grown along the trenches, followed by filling insulating materials (such as silicon dioxide (SiO₂), silicon nitride, silicon oxynitride, or the like) into the trenches with deposition processes. After that, an annealing process is performed on the insulating materials in the trenches, followed by performing the planarization process (such as chemical mechanical polish or the like) on the semiconductor on insulator substrate 100 to remove excessive insulating materials, so the insulating materials in the trenches are level with the top surface of the semiconductor on insulator substrate 100.

Referring to FIG. 3, the heavily doped region 442, the source region 444-1, and the source region 444-2 may be disposed within the well region 440, and may be extended downward from the upper surface of the well region 440. According to some embodiments of the present disclosure, the heavily doped region 442 may be the first conductive type (p-type), while the source region 444-1 and the source region 444-2 may be the second conductive type (n-type). The heavily doped region 442, the source region 444-1, and the source region 444-2 may be laterally adjoined with each other, and the heavily doped region 442 may be laterally sandwiched between the source region 444-1 and the source region 444-2. The formation of the heavily doped region 442, the source region 444-1, and the source region 444-2 may be similar to that of the well region 420, and the details are not described again herein to avoid repetition.

In some embodiments, the doping concentration of the heavily doped region 442 may be between 1×10¹ ⁸ cm⁻³ and 1×10²² cm⁻³. The heavily doped region 442 may be coupled to the subsequently formed source contacts 960S simultaneously with the source region 444-1 and the source region 444-2. The thickness of the heavily doped region 442 may be between 0.1μm and 0.5μm. According to some embodiments of the present disclosure, since the well region 440 and the heavily doped region 442 have the same conductive type, the heavily doped region 442 may serve as the source terminal main body that connects to the source region 444-1 and the source region 444-2, and may play a critical role for the source terminal to be electrically ground.

In some embodiments, the doping concentration of the source region 444-1 and the source region 444-2 may be between 1×10¹ ⁸ cm⁻³ and 1×10²² cm⁻³. The thickness of the source region 444-1 and the source region 444-2 may be between 0.1μm and 0.5μm. According to some embodiments of the present disclosure, the source region 444-1 and the source region 444-2 may function as the source terminal for the third transistor 10B-3.

Still referring to FIG. 3, the gate structure 620 of the first transistor 10B-1, the gate structure 640 of the second transistor 10B-2, and the gate structure 660-1 and the gate structure 660-2 of the third transistor 10B-3 may be disposed on the epitaxial layer 180. The portion of the well region 320 that is in contact with the gate structure 620 may be considered as the channel region for the first transistor 10B-1, and the gate structure 620 may serve as the gate terminal for the first transistor 10B-1. The gate structure 620 may be coupled to the subsequently formed gate contact 920G. The portion of the well region 340 that is in contact with the gate structure 640 may be considered as the channel region for the second transistor 10B-2, and the gate structure 640 may serve as the gate terminal for the second transistor 10B-2. The gate structure 640 may be coupled to the subsequently formed gate contact 940G. The gate structure 660-1 and the gate structure 660-2 may be extended from above the high-voltage well region 360 reaching above the well region 440 in the horizontal direction. The portion of the high-voltage well region 360 or the portion of the well region 440 that is in contact with the gate structure 660-1 and the gate structure 660-2 may be considered as the channel region for the third transistor 10B-3, and the gate structure 660-1 and the gate structure 660-2 may serve as the gate terminal for the third transistor 10B-3. The gate structure 660-1 and the gate structure 660-2 may be coupled to the subsequently formed gate contacts 960G, respectively.

In the third transistor 10B-3, the source region 444-1, the drain region 446-1, and the gate structure 660-1 may form a transistor of the second conductive type (n-type) (known as a first transistor hereafter), while the source region 444-2, the drain region 446-2, and the gate structure 660-2 may form another transistor of the second conductive type (n-type) (known as a second transistor hereafter). According to some embodiments of the present disclosure, the first transistor and the second transistor of the third transistor 10B-3 may be in parallel with each other. Therefore, the third transistor 10B-3 may appear to be an array-type structure, for example, the laterally double diffused metal-oxide semiconductor transistor.

The thickness of the gate structure 620, the gate structure 640, the gate structure 660-1, and the gate structure 660-2 may be between 20Å and 1000Å. In some embodiments, each of the gate structure 620, the gate structure 640, the gate structure 660-1, and the gate structure 660-2 may include a gate dielectric layer (not shown) and a gate electrode (not shown) disposed on the gate dielectric layer. The materials and the formation of the gate dielectric layer may be similar to those of the dielectric layer 520-1 and the dielectric layer 520-2, and the details are not described again herein to avoid repetition. The materials and the formation of the gate electrode may be similar to those of the electrode 680-1 and the electrode 680-2, and the details are not described again herein to avoid repetition.

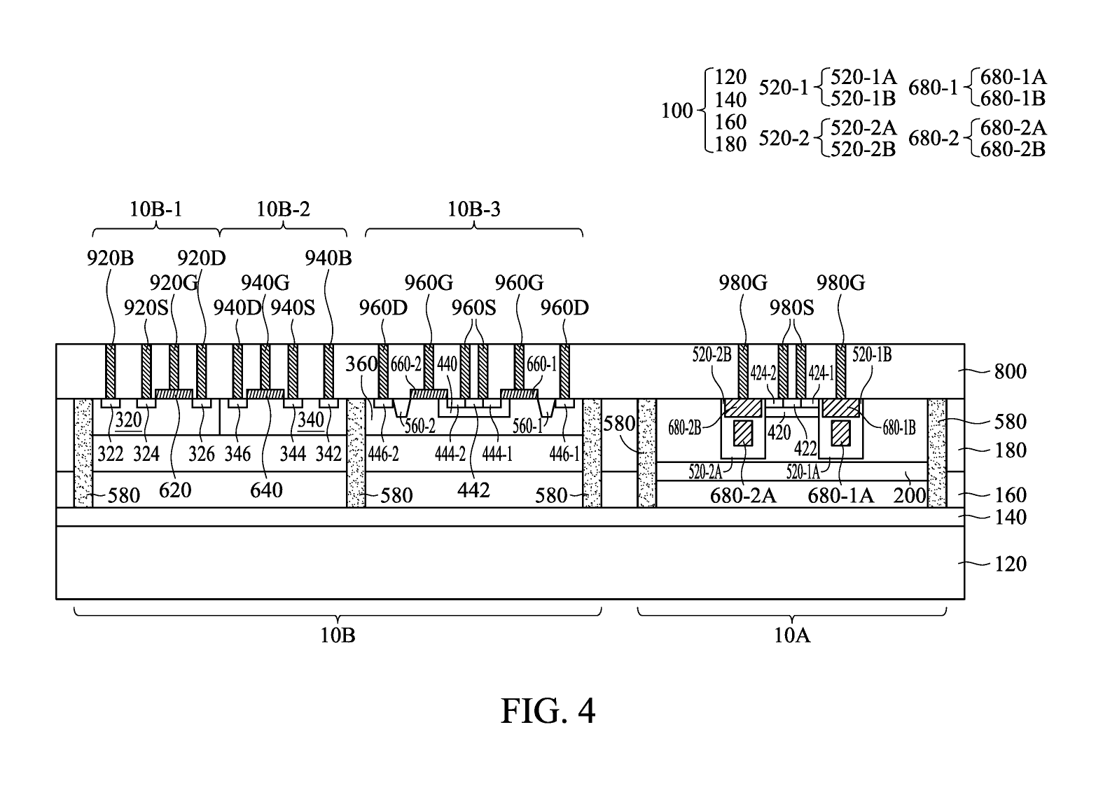

Referring to FIG. 4, an isolation structure 580 may be disposed in the semiconductor on insulator substrate 100. In some embodiments, the isolation structure 580 may be the deep trench isolation structure. The isolation structure 580 may be extended through the epitaxial layer 180 and the epitaxial layer 160, as well as reaching the insulating layer 140. According to some embodiments of the present disclosure, the isolation structure 580 may laterally surround and define the active regions, and may electrically isolate active region elements within or above the semiconductor on insulator substrate 100. The materials and the formation of the isolation structure 580 may be similar to those of the isolation structure 560-1 and the isolation structure 560-2, and the details are not described again herein to avoid repetition.

It should be appreciated that the isolation structure 580 may be extended into the insulating layer 140, but cannot be extended through the insulating layer 140. A typical bipolar complementary metal oxide semiconductor – double diffused metal oxide semiconductor transistor may utilize the junction design to achieve the isolation effect. However, such isolation is not complete. According to some embodiments of the present disclosure, the isolation structure 580 may be combined with the semiconductor on insulator substrate 100 (for example, the insulating layer 140) to achieve the complete isolation effect. From another perspective, the isolation structure 580 and the semiconductor on insulator substrate 100 (for example, the insulating layer 140) may be collectively considered as a “container” that accommodates individual active elements, and may isolate neighboring active elements to suppress any potential leakage and unwanted cross interference.

The isolation structure 580 may laterally surround the vertical active element (for example, the split-gate transistor) of the first region 10A and the horizontal active element (for example, the bipolar complementary metal oxide semiconductor – double diffused metal oxide semiconductor transistor) of the second region 10B, to achieve the complete isolation between the horizontal active element and the vertical active element, as shown in FIG. 4. Furthermore, the isolation structure 580 may further isolate the first transistor 10B-1 and the second transistor 10B-2 from the third transistor 10B-3. In other words, the isolation structure 580 may completely isolate the “bipolar complementary metal oxide semiconductor” portion from the “double diffused metal oxide semiconductor” portion in the horizontal active element.

Still referring to FIG. 4, an interlayer dielectric (ILD) layer 800 may be disposed on the semiconductor on insulator substrate 100. In some embodiments, the interlayer dielectric layer 800 may cover the gate structure 620, the gate structure 640, the gate structure 660-1, and the gate structure 660-2. In addition to providing mechanical protection and electrical insulation for the underlying structures, the interlayer dielectric layer 800 may also isolate conductive materials from different levels. The materials of the interlayer dielectric layer 800 may include silicon oxide, silicon nitride, silicon carbide, silicon oxynitride, silicon oxynitrocarbide (SiOₓN_{y}C_{1-x-y}, wherein x and y are in a range from 0 to 1), tetra ethyl ortho silicate (TEOS), undoped silicate glass, doped silicon oxide (such as boron-doped phosphosilicate glass (BPSG), fused silica glass (FSG), phosphosilicate glass (PSG), boron doped silicate glass (BSG), or the like), low-k dielectric materials, or the like.

The thickness of the interlayer dielectric layer 800 may be between 5000Å and 20000Å. The interlayer dielectric layer 800 may be formed by spin-on coating, chemical vapor deposition, high-density plasma chemical vapor deposition (HDP-CVD), plasma-enhanced chemical vapor deposition, low-pressure chemical vapor deposition (LPCVD), flowable chemical vapor deposition (FCVD), sub-atmospheric chemical vapor deposition (SACVD), the like, or a combination thereof. Next, the planarization process (such as chemical mechanical polish) may be performed on the interlayer dielectric layer 800, allowing the interlayer dielectric layer 800 to have a planar surface.

Referring to FIG. 4, the main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, and the gate contacts 980G may be disposed through the interlayer dielectric layer 800. In the first transistor 10B-1, the main body contact 920B, the source contact 920S, the drain contact 920D, and the gate contact 920G may physically contact the main body region 322, the source region 324, the drain region 326, and the gate structure 620, respectively. In the second transistor 10B-2, the main body contact 940B, the source contact 940S, the drain contact 940D, and the gate contact 940G may physically contact the main body region 342, the source region 344, the drain region 346, and the gate structure 640, respectively. In the third transistor 10B-3, the source contacts 960S, the drain contacts 960D, and the gate contacts 960G may physically contact the heavily doped region 442 and the source region 444-1 / the source region 444-2, the drain region 446-1 and the drain region 446-2, and the gate structure 660-1 and the gate structure 660-2, respectively. In the split-gate transistor of the first region 10A, the source contacts 980S and the gate contacts 980G may physically contact the heavily doped region 422 and the source region 424-1 / the source region 424-2, and the electrode 680-1 and the electrode 680-2, respectively.

The main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, and the gate contacts 980G may be formed together, thus include the same materials. The materials may be similar to those of the electrode 680-1 and the electrode 680-2, and the details are not described again herein to avoid repetition. Initially, openings may be formed in the interlayer dielectric layer 800 to correspond to the main body region 322, the source region 324, the drain region 326, the gate structure 620, the main body region 342, the source region 344, the drain region 346, the gate structure 640, the heavily doped region 442 and the source region 444-1 / the source region 444-2, the drain region 446-1 and the drain region 446-2, the gate structure 660-1 and the gate structure 660-2, the heavily doped region 422 and the source region 424-1 / the source region 424-2, and the electrode 680-1 and the electrode 680-2. Next, the materials mentioned above may be blanket deposited on the interlayer dielectric layer 800 through the suitable deposition process. The materials mentioned above may be filled into the openings to form the main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, and the gate contacts 980G.

In some embodiments, although the present disclosure only describes up to the manufacturing process of the main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, and the gate contacts 980G, but the present disclosure is not limited thereto. According to the requirements of the industry, any subsequent process may be performed using the structure shown in FIG. 4 as the basis. For example, the suitable back-end of line (BEOL) process may be performed above the semiconductor device 10, not shown for simplicity.

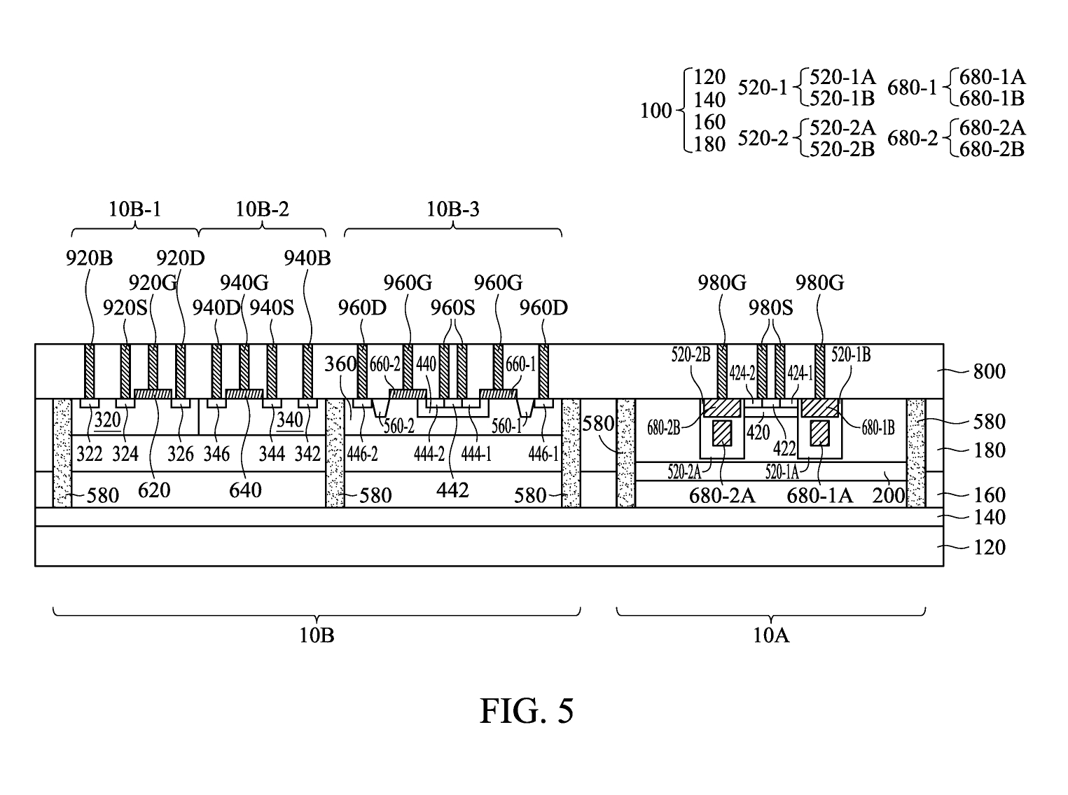

Referring to FIG. 5, the base plate 120 of the semiconductor on insulator substrate 100 may be thinned. The base plate 120 may be grinded to the desired thickness from the backside of the base plate 120, depending on application and design requirements. For example, the base plate 120 may be thinned to 19mil or 23mil. It should be appreciated that 1mil equals approximately 25.4μm. According to some embodiments of the present disclosure, thinning the base plate 120 may facilitate the formation of the subsequent opening, allowing the drain terminal of the split-gate transistor to be extended through the base plate 120 and the insulating layer 140, which in turn achieves the effective operation for the split-gate transistor. The base plate 120 may be thinned by Taiko grinding process, Non-Taiko grinding process, or the like.

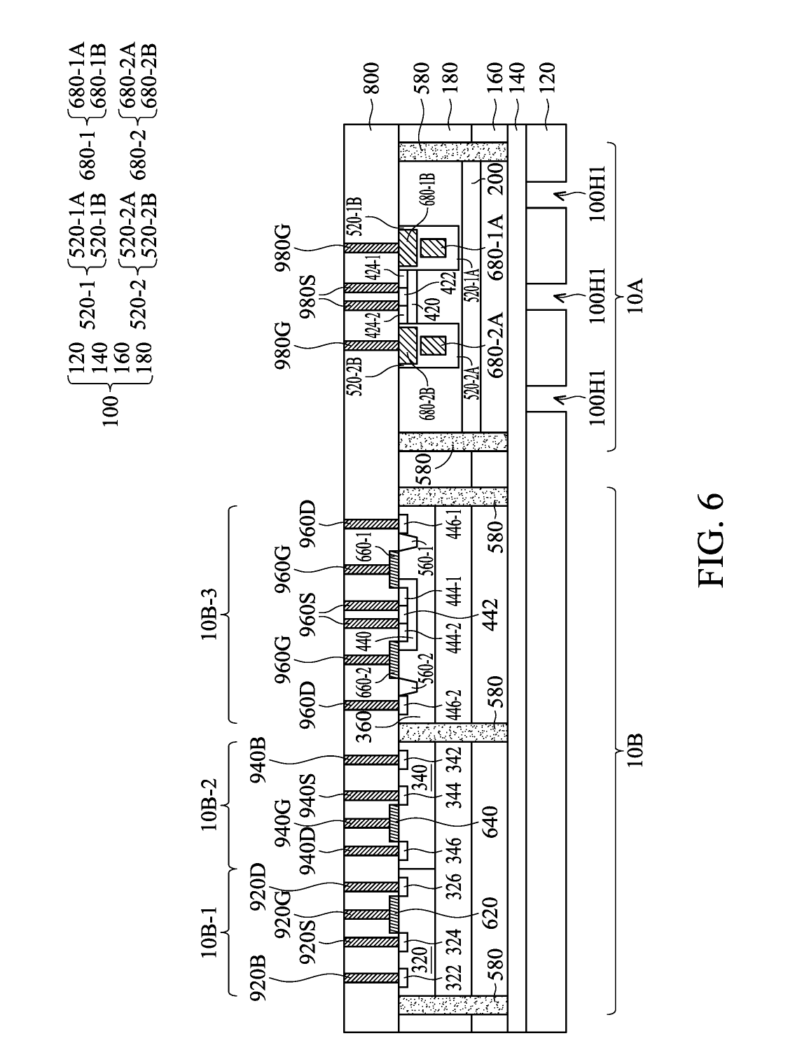

Referring to FIG. 6, a plurality of through holes 100H1 may be disposed in the base plate 120 after thinning the base plate 120. In some embodiments, the plurality of through holes 100H1 may be distributed across the first region 10A, and may be laterally spaced apart. According to some embodiments of the present disclosure, the plurality of through holes 100H1 may be extended through the base plate 120, and the insulating layer 140 may act as the etch stop layer (ESL). Since the material of the base plate 120 (for example, silicon) and the material of the insulating layer 140 (for example, oxide) have different etching rates, thus two etching processes are implemented to respectively etch the base plate 120 and the insulating layer 140, so a more superior etch selectivity may be achieved. Although three through holes 100H1 are illustrated in FIG. 6, but the present disclosure is not limited thereto. For example, any number of the through holes 100H1 may be configured, depending on application and design requirements. Initially, the patterned backside photoresist may be formed on the backside of the base plate 120, followed by performing the first etching process to etch the base plate 120 using the suitable etching process mentioned above, in order to form the plurality of through holes 100H1 from the backside of the base plate 120.

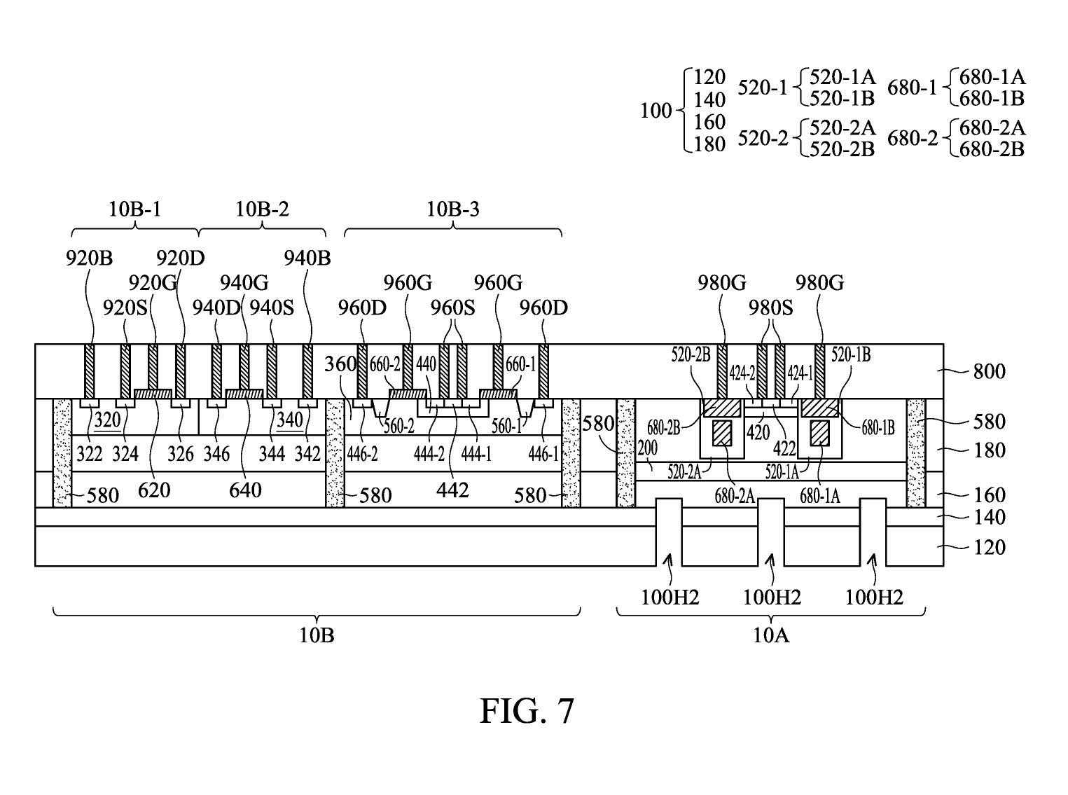

Referring to FIG. 7, the plurality of through holes 100H1 may be further extended through the insulating layer 140. In some embodiments, the plurality of through holes 100H1 may be extended into the epitaxial layer 160, and become a plurality of through holes 100H2. According to some embodiments of the present disclosure, the plurality of the through holes 100H2 may allow the subsequently formed drain electrode 740 to conduct, without being affected by the insulating layer 140. The lateral dimension of each through hole 100H2 may be between 1μm and 50μm. The second etching process may be performed to etch the insulating layer 140 by the suitable etching process mentioned above. For example, the dry oxide etching with time-mode may be utilized to control the extension of the plurality of through holes 100H2.

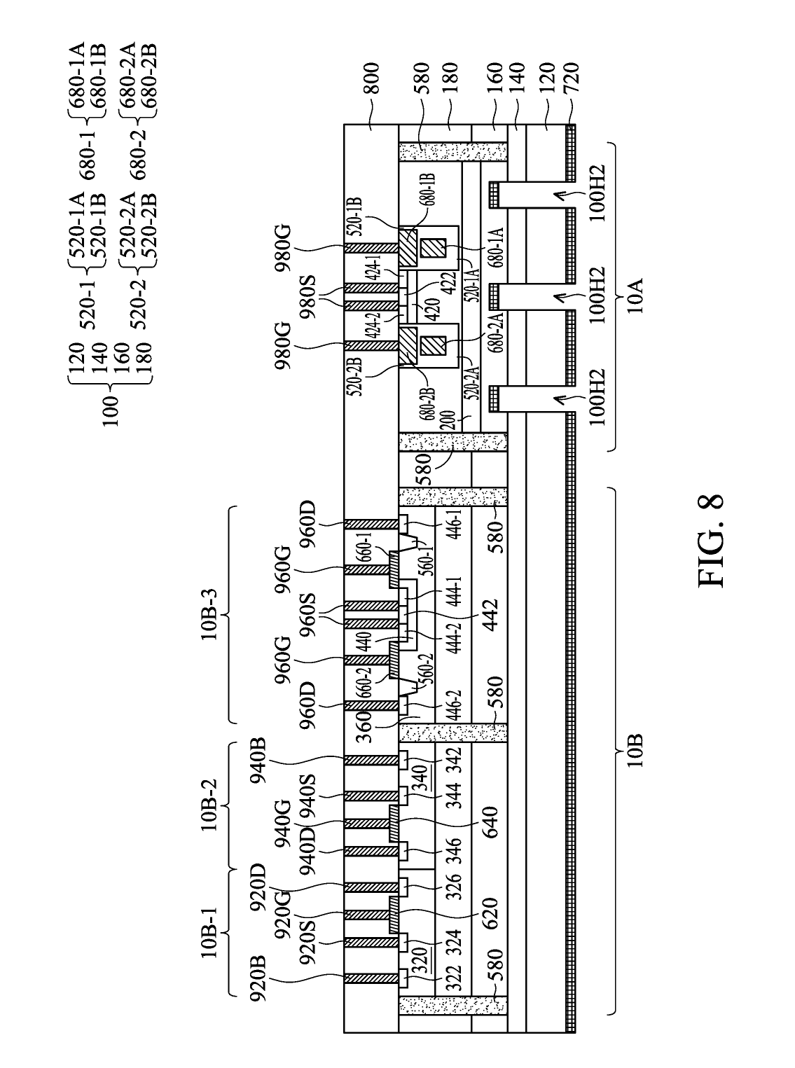

Referring to FIG. 8, a drain region 720 may be disposed in the base plate 120 before the manufacturing of the drain electrode 740. In some embodiments, the drain region 720 may be extended across the first region 10A and the second region 10B, and may be close to the backside surface of the base plate 120 and the bottom surface of the plurality of through holes 100H2. According to some embodiments of the present disclosure, the drain region 720 may lower the on-state resistance of the split-gate transistor of the first region 10A. If the on-state resistance of the split-gate transistor of the first region 10A needs to be further reduced, the portion of the drain region 720 close to the bottom surface of the plurality of through holes 100H2 may be configured to be in contact with the buried layer 200. The drain region 720 may be the second conductive type (n-type). The configuration of the drain region 720 may be optional. In other words, the drain region 720 may be omitted, and the drain electrode 740 may be formed directly on the backside of the base plate 120 and inside the plurality of through holes 100H2. It is worth noted that in general, the epitaxial concentration of the high-side region needs to be smaller than the epitaxial concentration of the low-side region. Therefore, if the vertical active element of the first region 10A is high-voltage application, then the configuration of the buried layer 200 and the drain region 720 is not necessary.

In some embodiments, the doping concentration of the drain region 720 may be between 5×10¹ ⁷ cm⁻³ and 1×10²⁰ cm⁻³. According to some embodiments of the present disclosure, the doping concentration of the drain region 720 may be larger than the doping concentration of the base plate 120. The suitable dopants may be blanket implanted in the base plate 120 through suitable implantation process. Next, the dopants may be driven into the base plate 120 by the annealing process. The suitable annealing process may include rapid thermal anneal (RTA), spike anneal, soak anneal, laser anneal, furnace anneal, or the like. Since no mask is implemented, the drain region 720 may be formed close to the backside surface of the base plate 120 and the bottom surface of the plurality of through holes 100H2.

Referring to FIG. 9, the drain electrode 740 may be disposed on the backside of the base plate 120 and in the plurality of through holes 100H2. In some embodiments, the drain electrode 740 may be extended across the first region 10A and the second region 10B, and may be conformally extended into each through hole 100H2. According to some embodiments of the present disclosure, the portion of the drain electrode 740 in the plurality of through holes 100H2 may serve as the effective drain terminal of the split-gate transistor of the first region 10A. The thickness of the drain electrode 740 may be between 0.1μm and 10μm. The materials and the formation of the drain electrode 740 may be similar to those of the electrode 680-1 and the electrode 680-2, and the details are not described again herein to avoid repetition.

It should be appreciated that the drain electrode 740 may be unable to extend conformally into the plurality of through holes 100H2 when the plurality of through holes 100H2 have very high aspect ratio. Under the circumstances when the plurality of through holes 100H2 have relatively narrow openings (for example, very small line width), the plurality of through holes 100H2 may first be filled with metallic materials (for example, tungsten). Furthermore, a liner of titanium / titanium nitride may first be deposited on the sidewalls and the bottom surface of the plurality of through holes 100H2 before filling the metallic materials. The metallic materials filling into the plurality of through holes 100H2 may function as conductive blocks. After that, the drain electrode 740 may be deposited on the backside of the base plate 120 and on the top surface of the metallic materials. It is worth noted that although the drain electrode 740 is also extended across the second region 10B, the drain electrode 740 may be electrically insulated from the horizontal active element of the second region 10B by the insulating layer 140 of the semiconductor on insulator substrate 100. Therefore, the drain electrode 740 will not cause any unwanted impact upon the horizontal active element of the second region 10B.

In the split-gate transistor of the first region 10A, the source region 424-1, the drain electrode 740, and the dielectric layer 520-1 and the electrode 680-1 may form a first transistor, while the source region 424-2, the drain electrode 740, and the dielectric layer 520-2 and the electrode 680-2 may form a second transistor. According to some embodiments of the present disclosure, the first transistor and the second transistor of the split-gate transistor may be in parallel with each other. Therefore, the split-gate transistor may appear to be an array-type metal-oxide semiconductor field effect transistor.

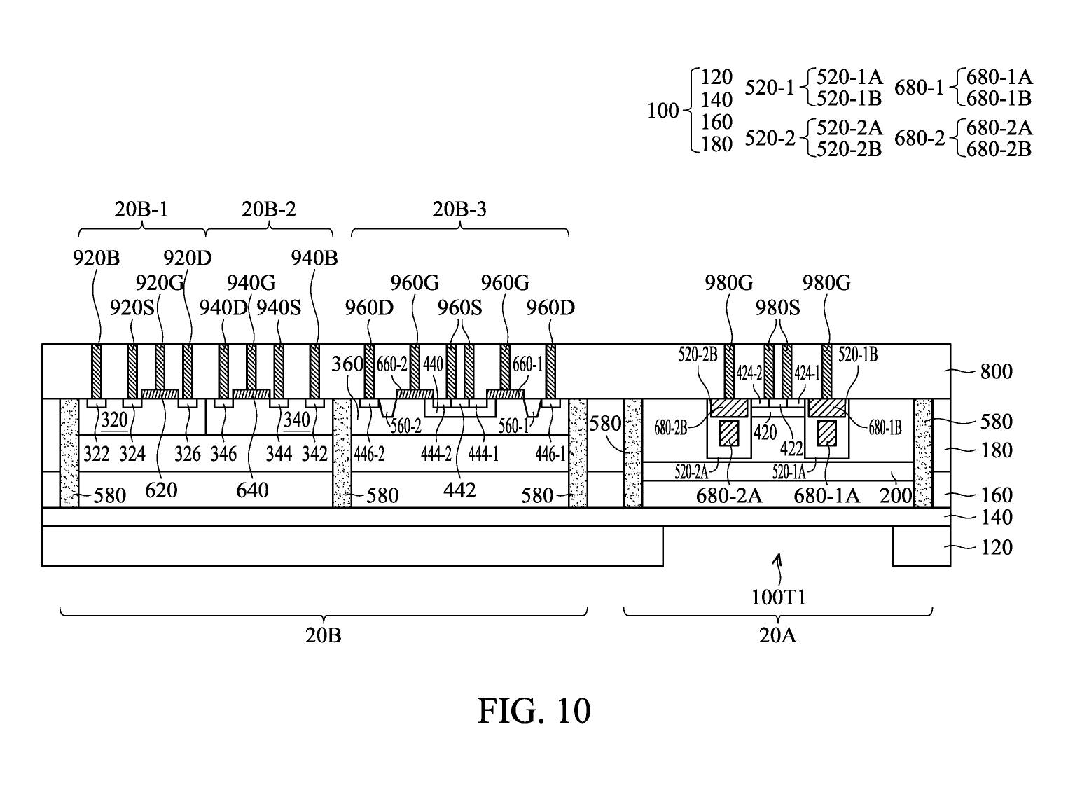

FIGS. 10-13 illustrate cross-sectional views of intermediate stages of a semiconductor device 20, according to other embodiments of the present disclosure. The semiconductor device 20 may be compartmentalized into a first region 20A and a second region 20B. The horizontal active element of the second region 20B may include a first transistor 20B-1, a second transistor 20B-2, and a third transistor 20B-3. In comparison with the semiconductor device 10, an opening with relatively larger dimension may be formed in the base plate 120 of the semiconductor on insulator substrate 100 of the semiconductor device 20. For simplicity, the features of the first region 20A and the second region 20B (including the first transistor 20B-1, the second transistor 20B-2, and the third transistor 20B-3) may be respectively similar to the features of the first region 10A and the second region 10B (including the first transistor 10B-1, the second transistor 10B-2, and the third transistor 10B-3), and the details are not described again herein to avoid repetition.

Referring to FIG. 10, in comparison with FIG. 6, a single trench 100T1 may be disposed in the base plate 120. In some embodiments, the trench 100T1 may overlap the heavily doped region 422 and the source region 424-1 / the source region 424-2, the dielectric layer 520-1 and the electrode 680-1, and the dielectric layer 520-2 and the electrode 680-2. According to some embodiments of the present disclosure, the trench 100T1 may be extended through the base plate 120, and the insulating layer 140 may act as the etch stop layer. As mentioned previously, since the material of the base plate 120 (for example, silicon) and the material of the insulating layer 140 (for example, oxide) have different etching rates, thus two etching processes are implemented to respectively etch the base plate 120 and the insulating layer 140, so a more superior etch selectivity may be achieved. The formation of the trench 100T1 may be similar to that of the plurality of through holes 100H1, and the details are not described again herein to avoid repetition.

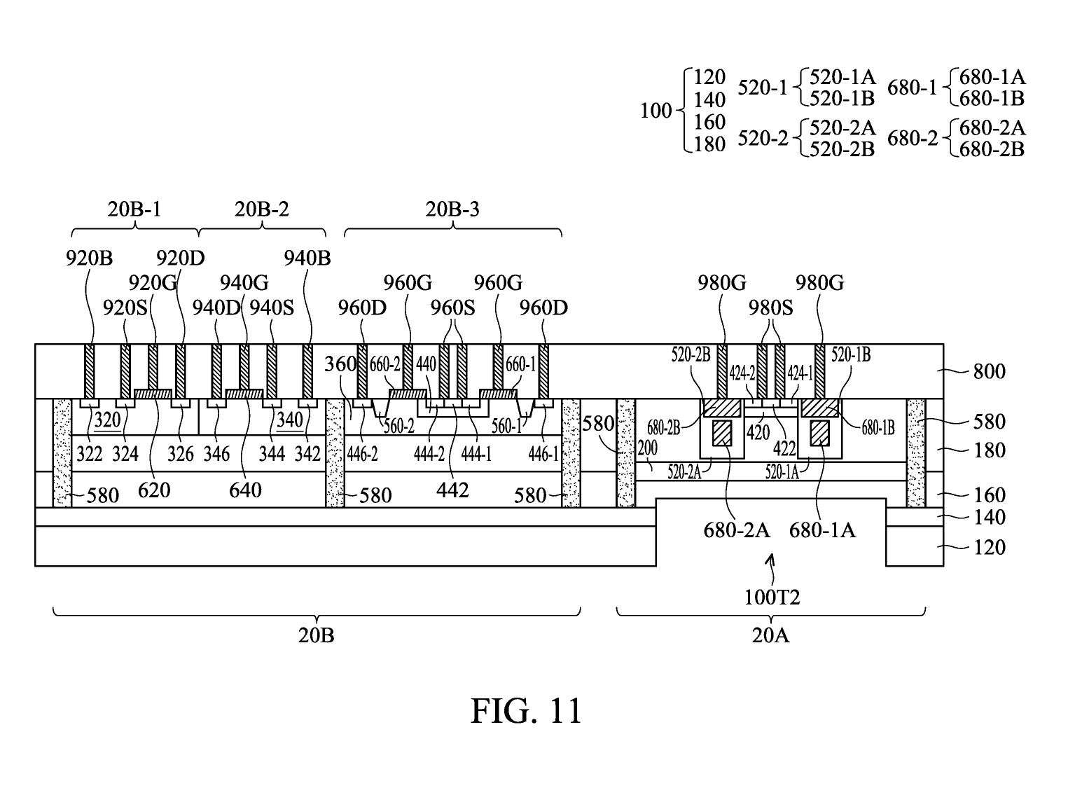

Referring to FIG. 11, the trench 100T1 may be further extended through the insulating layer 140. In some embodiments, the trench 100T1 may be extended into the epitaxial layer 160, and becomes a trench 100T2. According to some embodiments of the present disclosure, the trench 100T2 may allow the subsequently formed drain electrode 740 to conduct, without being affected by the insulating layer 140. The lateral dimension of the trench 100T2 may be between 50μm and 200μm. The formation of the trench 100T2 may be similar to that of the plurality of through holes 100H2, and the details are not described again herein to avoid repetition.

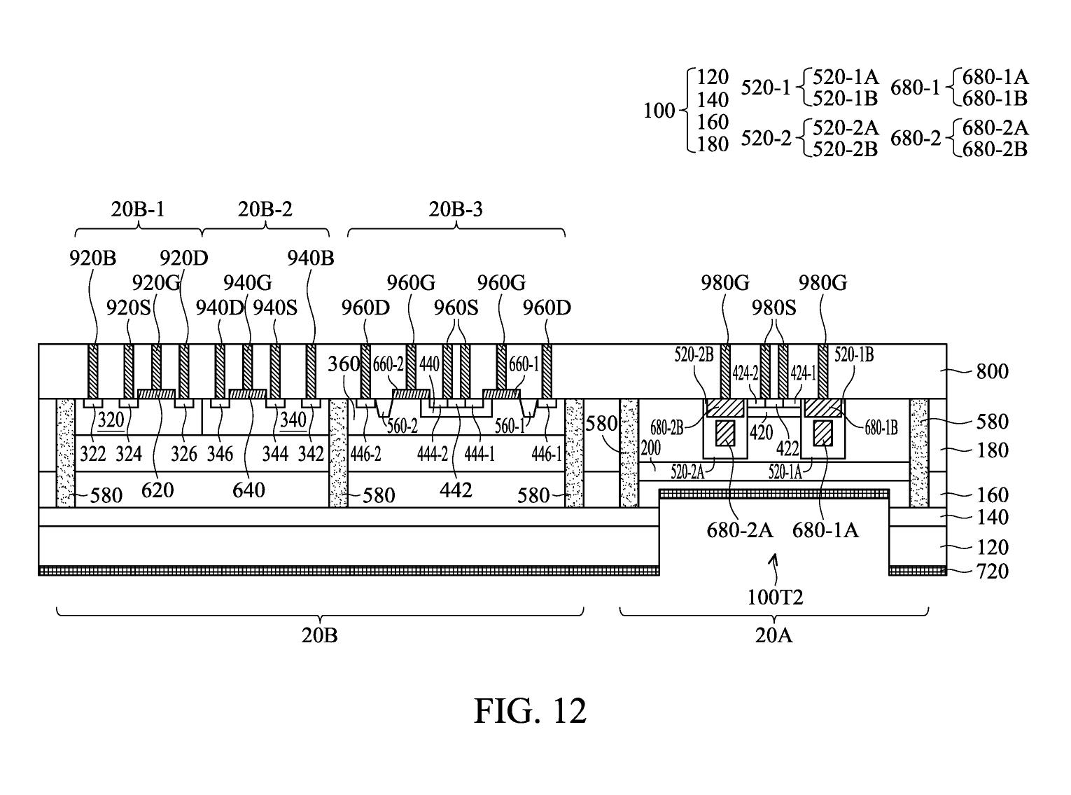

Referring to FIG. 12, the drain region 720 may be disposed in the base plate 120. In some embodiments, the drain region 720 may be extended across the first region 20A and the second region 20B, and may be close to the backside of the base plate 120 and the bottom surface of the trench 100T2. According to some embodiments of the present disclosure, the drain region 720 may reduce the on-state resistance of the split-gate transistor of the first region 20A. If the on-state resistance of the split-gate transistor of the first region 20A needs to be further reduced, the portion of the drain region 720 close to the bottom surface of the trench 100T2 may be configured to be in contact with the buried layer 200. The drain region 720 may be the second conductive type (n-type). As mentioned previously, the configuration of the drain region 720 may be optional. In other words, the drain region 720 may be omitted, and the drain electrode 740 may be formed directly on the backside of the base plate 120 and in the trench 100T2. The feature of the drain region 720 may be similar to that shown in FIG. 8, and the details are not described again herein to avoid repetition.

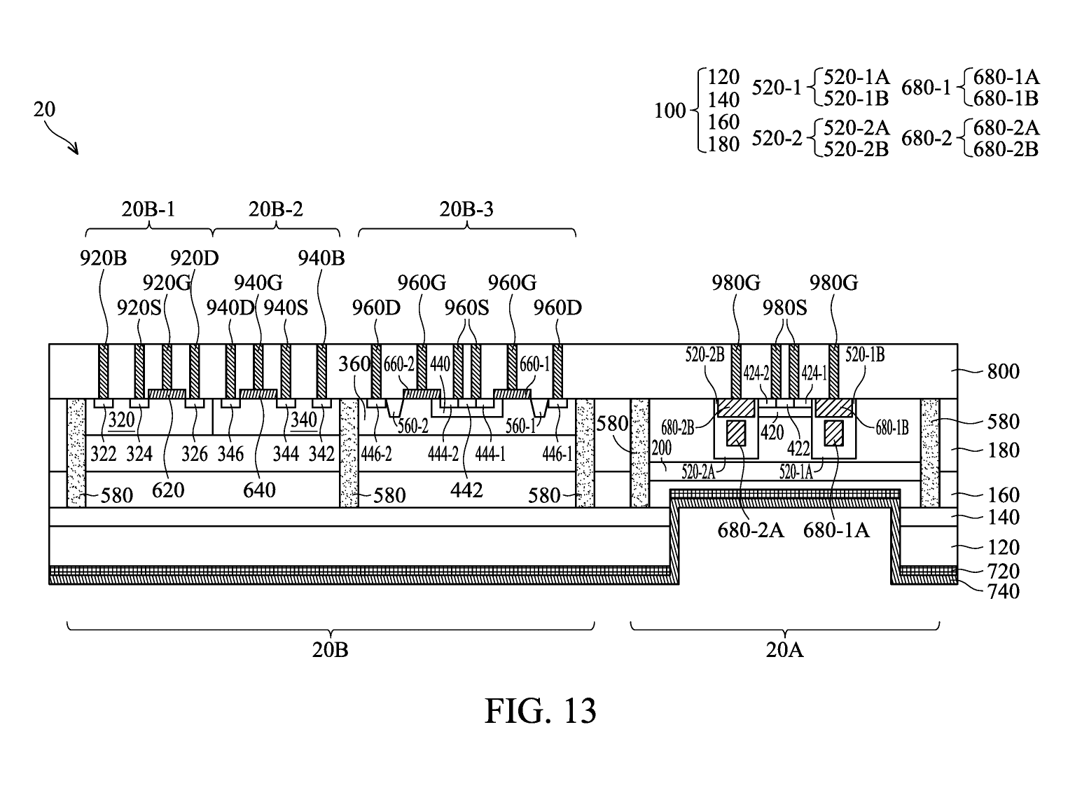

Referring to FIG. 13, the drain electrode 740 may be disposed on the backside of the base plate 120 and in the trench 100T2. In some embodiments, the drain electrode 740 may be extended across the first region 20A and the second region 20B, and may be conformally extended into the trench 100T2. According to some embodiments of the present disclosure, the portion of the drain electrode 740 in the trench 100T2 may serve as the effective drain terminal of the split-gate transistor of the first region 20A. As mentioned previously, the drain electrode 740 may be electrically insulated from the horizontal active element of the second region 20B by the insulating layer 140 of the semiconductor on insulator substrate 100. Therefore, the drain electrode 740 will not cause any unwanted impact upon the horizontal active element of the second region 20B. The feature of the drain electrode 740 may be similar to that shown in FIG. 9, and the details are not described again herein to avoid repetition.

In the present technology, the channel of the horizontal active element may be extended in the horizontal direction, while the channel of the vertical active element may be extended in the vertical direction. Therefore, if the horizontal active element and the vertical active element are to be disposed onto the same wafer, the horizontal active element and the vertical active element need to be formed in different manufacturing processes. Furthermore, since it is already difficult to achieve the effective isolation in the horizontal active element, the isolation may be even more challenging when the horizontal active element and the vertical active element are integrated. According to some embodiments of the present disclosure, the semiconductor on insulator substrate may be combined with the deep trench isolation structure to achieve the complete isolation. The deep trench isolation structure and the semiconductor on insulator substrate may be collectively considered as the “container” that accommodates the individual active elements, and may isolate neighboring active elements to suppress any potential leakage and unwanted cross interference. Moreover, in response to the implementation of the semiconductor on insulator substrate, the backside process may be utilized to design the drain electrode formed on the backside of the base plate of the semiconductor on insulator substrate to be extended through the base plate and the insulating layer, in order to constitute an innovative drain terminal. Such design may effectively prevent the insulating layer of the semiconductor on insulator substrate from electrically insulating the drain terminal on the backside of the base plate from the source terminal and the gate terminal on the frontside of the base plate, thereby causing device failure. Therefore, the horizontal active element and the vertical active element may be effectively integrated to achieve the complete isolation.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor on insulator (SOI) substrate, comprising:
a base plate; and
an insulating layer disposed on a frontside of the base plate;
a vertical active element disposed in a first region, comprising:
a pair of source regions disposed in the semiconductor on insulator substrate;
a pair of gate electrodes disposed at opposite sides of the pair of source regions, respectively; and
a drain electrode disposed on a backside of the base plate, wherein a portion of the drain electrode is disposed through the base plate and the insulating layer;
a horizontal active element disposed in a second region; and
an isolation structure separating the vertical active element from the horizontal active element.

2. The semiconductor device of claim 1, wherein the vertical active element is a discrete device, and the horizontal active element is a bipolar complementary metal oxide semiconductor – double diffused metal oxide semiconductor (BCD) transistor.

3. The semiconductor device of claim 2, wherein the discrete device comprises a split-gate transistor (SGT).

4. The semiconductor device of claim 1, wherein the insulating layer continuously extends across the first region and the second region.

5. The semiconductor device of claim 1, further comprising a heavily doped region sandwiched between the pair of source regions, wherein the heavily doped region has a first conductive type, while the pair of source regions has a second conductive type different from the first conductive type.

6. The semiconductor device of claim 5, wherein the heavily doped region laterally adjoins the pair of source regions.

7. The semiconductor device of claim 5, wherein the heavily doped region and the pair of source regions are disposed in a well region, wherein the well region has the first conductive type.

8. The semiconductor device of claim 5, wherein the semiconductor on insulator substrate further comprising a first epitaxial layer disposed on the insulating layer, and having the second conductive type, wherein the pair of source regions and the pair of gate electrodes are located in the first epitaxial layer.

9. The semiconductor device of claim 8, wherein the semiconductor on insulator substrate further comprising a second epitaxial layer disposed between the insulating layer and the first epitaxial layer, and having the second conductive type, wherein the portion of the drain electrode is located in the second epitaxial layer.

10. The semiconductor device of claim 9, wherein the isolation structure is a deep trench isolation (DTI) structure extending through the first epitaxial layer and the second epitaxial layer, and reaching the insulating layer.

11. The semiconductor device of claim 1, wherein the pair of gate electrodes further comprising:
a first structure having a first dimension; and
a second structure on the first structure, wherein the second structure has a second dimension larger than the first dimension.

12. The semiconductor device of claim 11, further comprising a gate dielectric layer, comprising:
a first portion disposed on opposite sides and a bottom portion of the first structure; and
a second portion disposed between the first structure and the second structure, and on opposite sides of the second structure.

13. The semiconductor device of claim 5, wherein the horizontal active element further comprising:
a first transistor having the second conductive type;
a second transistor adjoining the first transistor, and having the first conductive type, wherein the first transistor and the second transistor are metal-oxide semiconductor (MOS) transistors; and
a third transistor separating from the second transistor by the isolation structure, and having the second conductive type, wherein the third transistor is a lateral-diffused metal-oxide semiconductor (LDMOS) transistor.

14. A method of forming a semiconductor device, comprising:
providing a semiconductor on insulator substrate, comprising:
providing a base plate; and
forming an insulating layer on a frontside of the base plate;
forming a vertical active element in a first region, comprising:
forming a pair of source regions in the semiconductor on insulator substrate;
forming a pair of gate electrodes at opposite sides of the pair of source regions, respectively; and
depositing a drain electrode on a backside of the base plate;
etching the semiconductor on insulator substrate to form an opening through the base plate and the insulating layer from the backside of the base plate, wherein a portion of the drain electrode extends into the opening;
forming a horizontal active element in a second region; and
forming an isolation structure separating the vertical active element from the horizontal active element.

15. The method of claim 14, wherein forming the opening comprising:
performing a first etching process to extend the opening through the base plate; and
performing a second etching process to extend the opening through the insulating layer.

16. The method of claim 15, wherein the opening is a plurality of through holes distributing across the first region, and laterally spaced apart from each other.

17. The method of claim 15, wherein the opening is a trench overlapping with the pair of source regions and the pair of gate electrodes.

18. The method of claim 14, further comprising thinning the base plate of the semiconductor on insulator substrate before forming the opening.

19. The method of claim 18, further comprising performing an ion implantation process on the backside of the base plate and the opening after thinning the base plate.

20. The method of claim 14, wherein providing the semiconductor on insulator substrate further comprising:
forming a first epitaxial layer on the insulating layer, wherein the opening is extended into the first epitaxial layer; and
forming a second epitaxial layer on the first epitaxial layer, wherein the pair of source regions and the pair of gate electrodes are extended into the second epitaxial layer, wherein the isolation structure extends through the first epitaxial layer and the second epitaxial layer, and in physical contact with the insulating layer.
